(19) United States
(12) Patent Application Publication
(10) Pub. No.: US 2013/0039514 A1
(43) Pub. Date: Feb. 14, 2013

(54) METHOD AND APPARATUS FOR SUPPLEMENTING LOW FREQUENCY SOUND IN A DISTRIBUTED LOUDSPEAKER ARRANGEMENT

(71) Applicants: Anthony Michael Knowles, Liphook (GB); Christopher John Davies, Alton (GB)

(72) Inventors: Anthony Michael Knowles, Liphook (GB); Christopher John Davies, Alton (GB)

(73) Assignee: IML LIMITED, Liphook, Hampshire (GB)

(21) Appl. No.: 13/575,103

(22) PCT Filed: Jan. 25, 2011
(86) PCT No.: PCT/GB11/00091

§ 371 Date: Oct. 31, 2012

(30) Foreign Application Priority Data
Jan. 25, 2010 (GB) 1001189.8

(51) Int. Cl. H03G 3/00

(52) U.S. Cl. 381/107

(57) ABSTRACT

An audio communication system is provided for generating an audio output for users in a region, the system comprising a plurality of portable communications devices for use by a respective plurality of users, each communications device comprising a microphone for inputting an audio signal by a user, a loudspeaker for generating an audio output for said user, said loudspeaker being adapted to output said audio output in at least a first frequency band, and a wireless interface for wireless communication to transmit said audio signals from said microphone and receive audio signals derived from an audio source for generating said audio output by said loudspeaker; and at least one low frequency loudspeaker device having an interface for receiving audio signals derived from a microphone of another communications device, and a low frequency loudspeaker adapted to output a low frequency audio output in said region only in a second frequency band lower than said first frequency band.

### FIELD OF THE INVENTION

The present invention relates to an audio system and method for generating an audio output for listeners in a region using at least one low frequency loudspeaker to supplement the output of a plurality of distributed loudspeakers.

### BACKGROUND OF THE INVENTION

In an arrangement for generating an audio output in the form of sound in a region for a plurality of listeners in the region, various well know problems exist. This is particularly the case if the audio output is speech since high clarity is required. The problems include echoes which can occur of surfaces in the region or boundaries around the region e.g. walls of a room. Also background noise can reduce audibility of sound in the region. The use of multiple sound sources (loudspeakers) in the region can cause time delays between sounds reaching a listener from the source thus reducing intelligibility of the sound. Further, when a microphone is used by a speaker for broadcast over multiple loudspeakers in the region there is a risk of feedback, particularly if the microphone is moved around the region e.g. by a roaming speaker or by the microphone being passed to different participants in the region.

To provide adequate sound volume and uniformity for listeners in the region, multiple loudspeakers are required. However, to provide sound across a broad frequency range for high listening quality requires loudspeakers that can provide a good output across a wide frequency range. Also a great deal of skill can be involved in designing the arrangement of the loudspeakers in a volume to provide the best listening experience for listeners located in the region. While this can reduce the problem of sound delays between sounds from different loudspeakers, echoes and feedback, it cannot be completely avoided and involves significant effort and cost.

It is therefore an object of the present invention to provide an improved audio system and method for generating sound for listeners in a region.

### SUMMARY OF THE INVENTION

The inventors of the present invention have realised that loudspeakers having a mid to high frequency response which are typically low quality loudspeakers can be provided to each listener in the region to provide personal sound output for the listener. Such loudspeakers may for example be provided in a handset which can be portable such as a communications device but the listener is not required to wear headphones or an ear piece which can be inconvenient and uncomfortable. The sound generated by such loudspeakers is thus targeted at each listener and the likelihood of interference of the output sound with sound from another loudspeaker is reduced i.e. the problem of time delays is reduced. However, such loudspeakers suffer from a poor low frequency response. The low frequency part of sounds, particularly speech provides the warmth. Thus the inventors have realised that due to psychoacoustics, listeners are less able to locate the source of low frequency sound and hence the localised mid to high frequency output from the distributed loudspeakers can be supplemented by at least one low frequency loudspeaker in the region. The directionally perceived sound from the communication device is therefore supplemented by the omnidirectionally perceived low frequency sound from the at least one low frequency loudspeaker.

In an arrangement that allows participants in a gathering to speak, personal mobile communications handsets having both a loudspeaker and a microphone can be provided to each participant. This allows the participants to listen to what is said by other participants and to speak themselves. The inventors have realised that the low frequency response of the loudspeakers of such handsets is poor and the audio experience of the users in a region can be enhanced by the provision of a separate low frequency audio output in the region.

One aspect of the present invention provides an audio communication system for generating an audio output for users in a region, the system comprising a plurality of portable communications devices for use by a respective plurality of users in the region, each communications device comprising a microphone for inputting an audio signal by a user, a loudspeaker for generating an audio output for said user, said loudspeaker being adapted to output said audio output in at least a first frequency band, and a wireless interface for wireless communication to transmit said audio signals from said microphone and receive audio signals derived from a microphone of another communications device in the region for generating said audio output by said loudspeaker; at least one low frequency loudspeaker device having an interface for receiving audio signals derived from said microphone of the other communications device, and a low frequency loudspeaker adapted to output a low frequency audio output in said region only in a second frequency band lower than said first frequency band; and a control unit for communicating with and controlling communications of said wireless interfaces and the or each said interface, wherein said control unit is adapted to receive said audio signal derived from said microphone of at least one said communications device in said region and to broadcast said audio signal to said wireless interfaces and said at least one low frequency loudspeaker device.

Another aspect of the present invention provides an audio communication method for generating an audio output for users in a region, the method comprising providing a plurality of users with a respective plurality of portable communications devices in the region, each communications device comprising a microphone, a loudspeaker, and a wireless interface; receiving an audio signal from a user using a said microphone of a said communications device in the region; transmitting said audio signals from said microphone and receiving audio signals derived from a microphone of another said communications device in the region using said wireless interface; generating an audio output in at least a first frequency band by said loudspeaker for said user; receiving audio signals derived from said microphone of at least one other communications device at an interface of at least one low frequency loudspeaker device; and outputting a low frequency audio output in said region only in a second frequency band lower than said first frequency band using a low frequency loudspeaker.

Thus in this aspect of the present invention, the audio capabilities of mobile handsets can be employed in the provision of an audio system for audio presentation to listeners in a region from an audio source. This avoids the need for separate loudspeakers to be arranged in the region and for cabling of a region for audio output. Each listener is provided with a dedicated mid to high frequency loudspeaker in their communications device. The listeners can be mobile within the region and still listen to the broadcast audio via the combination of the mid to high frequency output from the communications device and the low frequency output from the low frequency loudspeaker or loudspeakers. The microphones of the handsets enable users of the communications devices to be able to participate in a meeting and an easy method of enabling them to be heard is provided. There is no need for a ‘roaming’ microphone or dedicated microphones to be used. The integrated capability of the mobile communications device is utilised.

The portable communications devices can comprise devices specially adapted for the audio system or general purpose wireless communication devices such as mobile telephones or so called ‘smart phones’ adapted or programmed to act as audio communications devices. Also, in an embodiment employed in a voting arrangement, the communications devices can comprise voting handsets which are capable of registering votes input by participants. Thus this aspect of the invention utilises the capability of communications devices already available to listeners in the regions to provide a convenient targeted audio output enhanced by low frequency sound generated in a non-localised manner in the region.

In one embodiment the interface of said at least one low frequency loudspeaker device is adapted to receive said audio signal for said first and second frequency band, and said at least one low frequency loudspeaker device includes a low pass filter to pass only said second frequency band to drive said low frequency loudspeaker. Thus in this embodiment, the at least one low frequency loudspeaker can receive the same acoustic drive signal as the loudspeakers of the communications devices.

In one embodiment the interface of said at least one low frequency loudspeaker device is adapted to receive said audio signal for only said second frequency band to drive said low frequency loudspeaker. In this embodiment the need for a low pass filter in the low frequency loudspeaker unit is avoided but a signal transmission arrangement is needed that is able to generate a low frequency acoustic drive signal for the at least one low frequency loudspeaker.

One embodiment includes a control unit for communicating with and controlling communications of said wireless interfaces and the or each said interface. In this embodiment, the array of loudspeakers in the communications devices and the at least one low frequency loudspeaker require a common control unit for controlling signals to the loudspeakers.

In one embodiment a said portable communications device is adapted to operate as the control unit to communicate with and control communications of said wireless interfaces and said interface. This avoids the need for a separate control unit.

In one embodiment the control unit is adapted to receive said audio signals derived from said audio source and to broadcast said audio signals to said wireless interfaces and said at least one low frequency loudspeaker device.

In one embodiment the interface of at least one of said at least one low frequency loudspeaker device comprises a wireless interface for wireless communication to receive said audio signals.

In one embodiment the interface of at least one of said at least one low frequency loudspeaker device comprises a wireless interface for wireless communication to receive said audio signals; and said portable communications device adapted to operate as a control unit is adapted to receive said audio signals and to broadcast said signals to said wireless interfaces and said at least one low frequency loudspeaker device.

In one embodiment the interface of at least one of said at least one low frequency loudspeaker device comprises a wireless interface for wireless communication to receive said audio signals in said second communications channel.

In one embodiment the control unit is adapted to receive said audio signal, and to mix said audio signal for broadcast of said mixed audio signal to said wireless interfaces and said at least one low frequency loudspeaker device.

In one embodiment the portable communications device adapted to operate as a control unit is adapted to receive said audio signal derived from a plurality of audio sources, and to mix said audio signal for broadcast of said mixed audio signal to said wireless interfaces and said at least one low frequency loudspeaker device. The audio sources can be a number of speakers microphones on their communications devices, or auxiliary inputs e.g. from music systems, radio channels etc.

In one embodiment at least one said loudspeaker of said portable communications devices is adapted to output a majority of said audio output in said first frequency band. In this embodiment, at least one of the loudspeakers of the communications devices has a poor low frequency response.

In one embodiment at least one said loudspeaker of said portable communications devices is adapted to output only said audio output in said first frequency band. In this embodiment, at least one of the loudspeakers of the communications devices has no low frequency response.

### BRIEF DESCRIPTION OF THE DRAWINGS

FIG. 1 is a schematic diagram of an audio communication system in accordance with one embodiment of the present invention;

FIG. 2 is a schematic diagram of an audio communication system in accordance with another embodiment of the present invention;

FIG. 3 is a schematic diagram showing a first distribution of portable communication devices and low frequency loudspeaker units in accordance with one embodiment of the present invention;

FIG. 4 is a schematic diagram showing a second distribution of portable communication devices and low frequency loudspeaker units in accordance with one embodiment of the present invention;

FIG. 5 is a schematic diagram of a loudspeaker unit in accordance with one embodiment of the present invention;

FIG. 6 is a schematic diagram of a portable communications device in accordance with one embodiment of the present invention; and

FIG. 7 is a schematic diagram of a public address system according to one embodiment of the present invention.

### DETAILED DESCRIPTION OF EMBODIMENTS

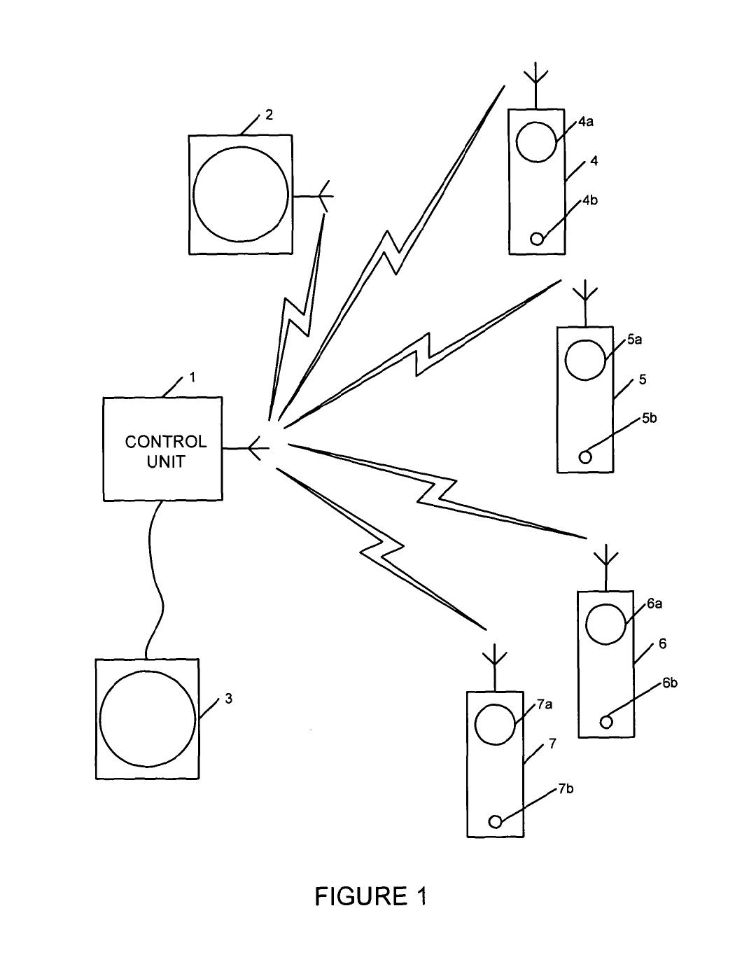

Embodiments of the present invention utilising communications handsets as mobile low frequency loudspeaker units will now be described with reference to FIGS. 1 to 6.

FIG. 1 illustrates an audio system in accordance with one embodiment of the present invention. In this system a plurality of mobile communications devices in the form of handsets 4, 5, 6, and 7 are provided in a region in which it is desired to provide an audio output. The region can comprise a room, hall, arena, stadium or just an open air region. The handsets 4, 5, 6, and 7 can comprise conventional mobile telephones for example equipped with a range limited wireless bandwidth capability such as Bluetooth™, or DECT and which are programmed to operate to receive audio signals broadcast over a wireless communication channel so as to act as loudspeakers in the audio system.

Each handset 4, 5, 6, and 7 is provided with a loudspeaker 4a, 5a, 6a, and 7a and a microphone 4b, 5b, 6b, and 7b.

In a system for use in a voting application the handsets 4, 5, 6, and 7 can comprise handsets having voting functionality such as disclosed in WO2004/017662, the whole contents of which is hereby incorporated by reference. In such an arrangement, the handsets 4, 5, 6, and 7 can enable participants in a gathering to enter inputs such as votes or responses to questions. Voting or response handsets are common in the prior art for meetings that require user participation. While it is known to provide such handsets with an audio communication capability, the audio output quality from the loudspeakers in the units has been poor.

The audio output quality of loudspeakers 4a, 5a, 6a, and 7a of the handsets 4, 5, 6, and 7 is limited due to the need to keep the size of the handset compact. Thus typically the frequency response of the loudspeakers 4a, 5a, 6a, and 7a is limited in the low frequency region. This gives the output a ‘tinny’ or ‘cold’ feel and the intelligibility of the output can be reduced. For example, handsets can have loudspeaker frequency responses that lie in the range of 300 Hz to several kHz and hence the frequency response in the low frequency region can be poor or no existent. The region of 100 Hz to 300 Hz and particularly around 200 Hz is important to provide ‘warmth’ to the audio perceived by the listener, particularly to speech. The region below 100 Hz is less important in this system and is usually reserved for high quality sound systems.

Thus the handsets 4, 5, 6, and 7 can provide audio output directly to individual listeners. The loudspeakers 4a, 5a, 6a, and 7a are capable of generating sufficient volume that they need not be held close to the ear of the listener but instead can be placed in the lap of the user or on a desk or table in from the of the listener for example.

Low frequency loudspeaker units 2 and 3 are provided in the region for generating low frequency sound to supplement the sound heard by the listeners from their handsets 4, 5, 6, and 7. The sound emitted by the low frequency loudspeaker units 2 and 3 can be in the range of 100 Hz to 300 Hz, or more generally below about 250-350 Hz. The sound is generated in the region directed to the listeners in a manner that causes the listeners to perceive the low frequency sound as omnidirectional. This is due to the psychoacoustic effect whereby listeners generally have difficulty in perceiving the location of the source of low frequency sound. Although in this embodiment two low frequency loudspeaker units 2 and 3 are provided, any number may be used.

The low frequency loudspeaker units 2 and 3 are arranged to receive wireless audio signals to generate the low frequency audio output. In this way, the placement of all the loudspeakers 2, 3, 4a, 5a, 6a, and 7a in the region is simple and flexible and requires no routing of cables. The low frequency loudspeaker units 2 and 3 can also be readily moved during an audio session if required. The handsets 4, 5, 6, and 7 are of course mobile during an audio session in the region. The handsets 4, 5, 6 and 7 can be provided to listeners specifically for the audio event or listeners can bring their own handsets e.g. mobile phones, and have them programmed to act as handsets for the audio session.

A control unit 1 is provided in this embodiment to generate and control communications to and from the handsets 4, 5, 6 and 7 and to the low frequency loudspeaker units 2 and 3. In this embodiment the low frequency loudspeaker unit 3 is connected to the control unit 1 by a wired connection. The low frequency loudspeaker unit 2 is connected to the control unit 1 by a wireless communication link. In this embodiment, the only audio sources available are the microphones 4b, 5b, 6b, and 7b of the handsets 4, 5, 6, and 7. Any number of these can output audio signals for broadcast to all of the loudspeakers 2, 3, 4a, 5a, 6a and 7a. Thus the control unit 1 receives audio signals from any microphones 4b, 5b, 6b, and 7b and broadcasts it to all of the loudspeakers 2, 3, 4a, 5a, 6a and 7a. If there is an audio signal input by more than one microphone 4b, 5b, 6b, and 7b, the control unit 1 can mix the audio signals for broadcast.

The control unit 1 can also receive audio signals from other sources (not shown) such as a radio source, a music source, a communication channel (e.g. a telephone line) etc and can mix the audio signals with the audio signals from the microphones 4b, 5b, 6b and 7b for broadcast.

The audio signal used for all of the loudspeakers 2, 3, 4a, 5a, 6a and 7a is derived from the common audio source, which can be one or more microphones 4b, 5b, 6b or 7b or an auxiliary audio source. The audio signal to the low frequency loudspeaker units 2 and 3 can be filtered prior to transmission to them by the control unit 1 so as to remove the mid to high frequency components so that the audio signal can be used directly to drive low frequency loudspeakers. Alternatively, the low frequency loudspeaker units 2 and 3 can receive the same signal as the loudspeakers 4a, 5a, 6a and 7a and the signal can be low pass filtered at each of the low frequency loudspeaker units 2 and 3 to generate the low frequency drive signal for the low frequency loudspeakers.

In this embodiment, the control unit can use a common transmit channel for the handsets 4, 5, 6 and 7. If the low frequency loudspeaker units 2 and 3 receive the same signal, the same transmit channel can be used. If the signal for the low frequency loudspeaker units 2 and 3 is low pass filtered before transmission, then a separate transmit channel can be used. Each handset can be assigned its own transmit channel to avoid conflicts. The assignment of the channels can be controlled by the control unit 1.

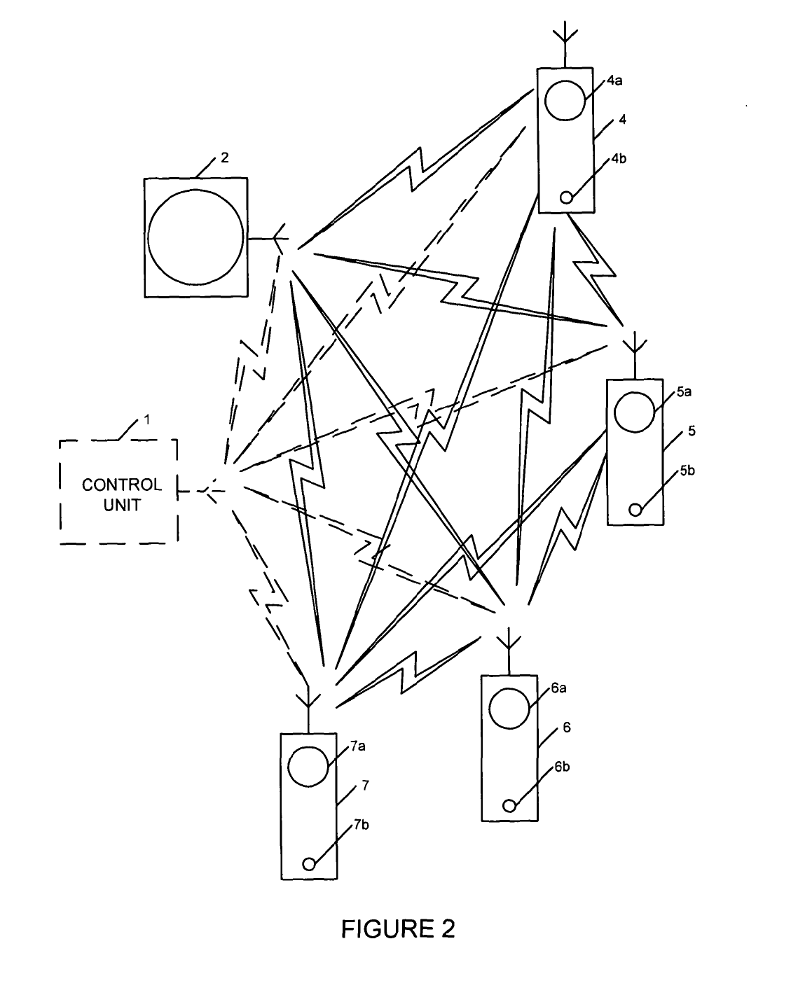

FIG. 2 illustrates an alternative embodiment of the present invention which is similar to the embodiment of FIG. 1 except that no wired low frequency loudspeaker unit is provided and the handsets 4, 5, 6, and 7 and the low frequency loudspeaker 2 can communicate directly over a wireless communication network of one of more wireless channels.

In one embodiment the control unit 1 is present to provide control over the communication timing and synchronisation to avoid conflicts e.g. when two handsets try to transmit audio signals on the same communications channel. The control unit 1 can assign communication channels dynamically to handsets 4, 5, 6, and 7 to allow direct handset to handset communication.

In another embodiment, no control unit is present but one of the handsets acts as the control unit or base station and has the same functionality. In yet another embodiment, no control unit is present and the handsets 4, 5, 6, and 7 can use a common channel to listen on for audio to be output and each handset has to be given control to transmit onto the channel e.g. the handset may have a ‘press to speak’ button that sends a signal to a master handset to ask for control of the channel or automatically takes control of the channel when pressed. In such a distributed system, there is no control unit to mix audio signals from multiple sources e.g. microphones and hence only one audio signal from one audio source can be broadcast to the loudspeakers 2, 4a, 5a, 6a, and 7a at a time.

The handsets 4, 5, 6 and 7 can generate a single common signal for the low frequency loudspeaker units 2 and 3 and the handsets 4, 5, 6 and 7 on a single channel (or single transmit channel per handset when each handset uses a separate transmit channel). Alternatively, each handset 4, 5, 6 and 7 can perform the low frequency filtering to generate a low frequency transmit signal on a transmit channel for the low frequency loudspeaker units 2 and 3 separate from the mid to high frequency transmit channel for the handsets 4, 5, 6 and 7. When a control unit 1 is present, the control unit 1 will use a further 1 or 2 transmit channels, one for the low frequency signal to the low frequency loudspeaker units 2 and 3 if the low frequency loudspeaker units 2 and 3 are wirelessly connected to the control unit 1, and one for transmission of signals to the handsets 4, 5, 6 and 7.

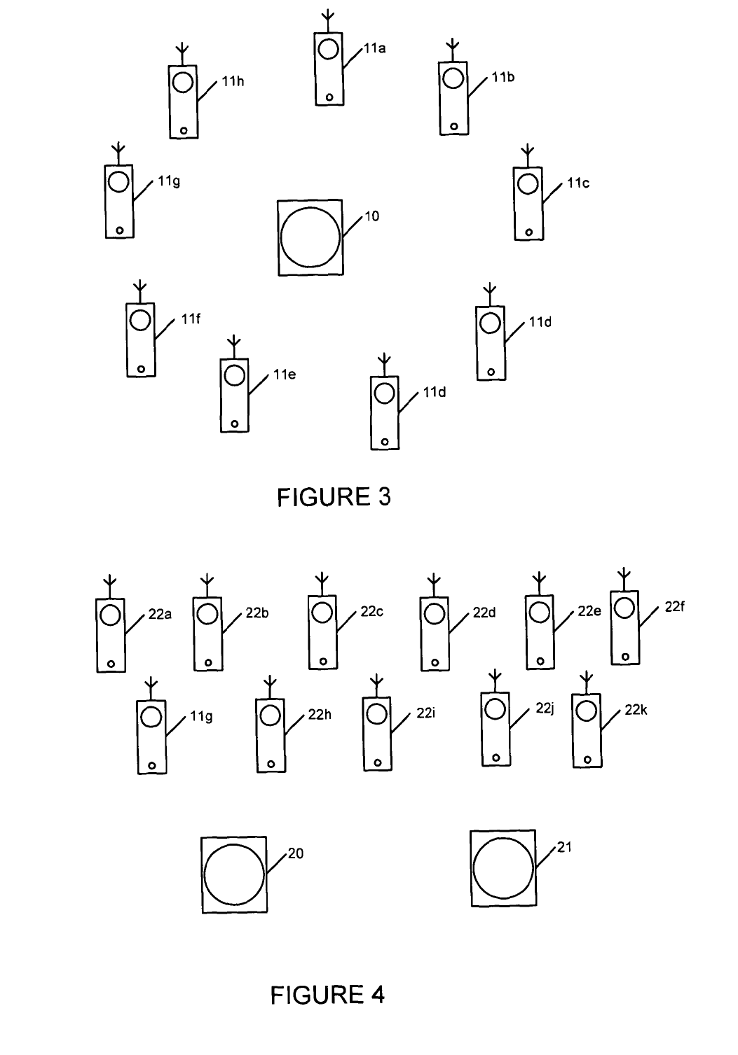

FIG. 3 illustrates one configuration of handsets 11a-h and a single low frequency loudspeaker unit 10 in accordance with one embodiment of the present invention. In this arrangement only a single low frequency loudspeaker unit 10 is provided and the handsets 11a-h are arranged around it so that the low frequency loudspeaker unit 10 is generally arranged in the centre of the region for the audio session.

FIG. 4 illustrates an alternative configuration in which a plurality of handsets 22a-k are arranged in rows e.g. in the possession of conference participants sitting in rows of an auditorium. Two low frequency loudspeaker units 20 and 21 are provided in front of the rows of handsets 22a-k to supplement the low frequency audio to the listeners holding the handsets 22a-k.

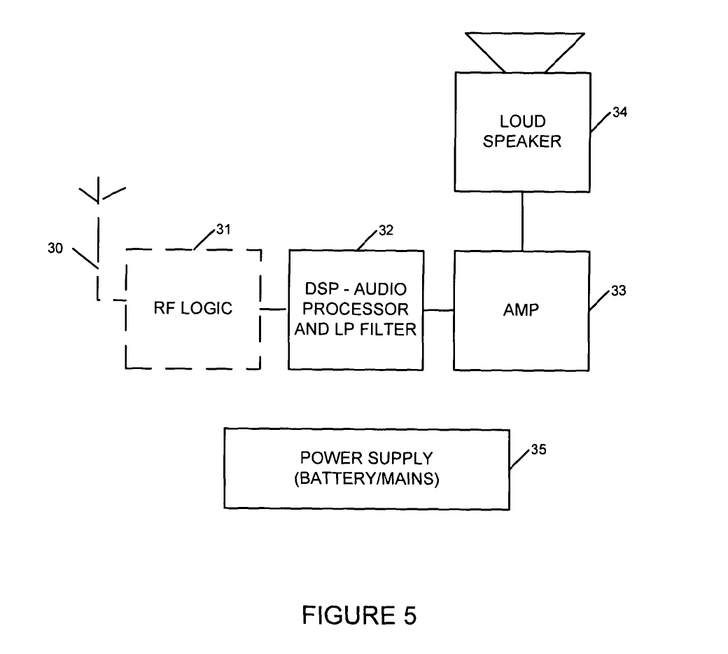

FIG. 5 illustrates the structure of the low frequency loudspeaker unit in accordance with one embodiment of the present invention.

The low frequency loudspeaker unit is provided with a wireless antenna 30 for the reception of radio frequency (RF) modulated audio signals. A Radio Frequency (RF) logic unit 31 is provided to down convert the received RF signals. The antenna 30 and the RF logic unit 31 are present in the low frequency loudspeaker unit 2. They are not present in the low frequency loudspeaker unit 1, which instead has a wired connection.

A digital signal processor (DSP) 32 provides for audio signal processing and low pass filtering if required. An amplifier (AMP) 33 is provided for amplifying the received audio signals to drive a loudspeaker 34 having a good low frequency response i.e. having a good response below 250-350 Hz, e.g. 100-300 Hz.

The circuitry of the low frequency loudspeaker unit is powered by a power supply 35 which is battery power supply to enable the low frequency loudspeaker unit to be mobile, or it can be a mains supply.

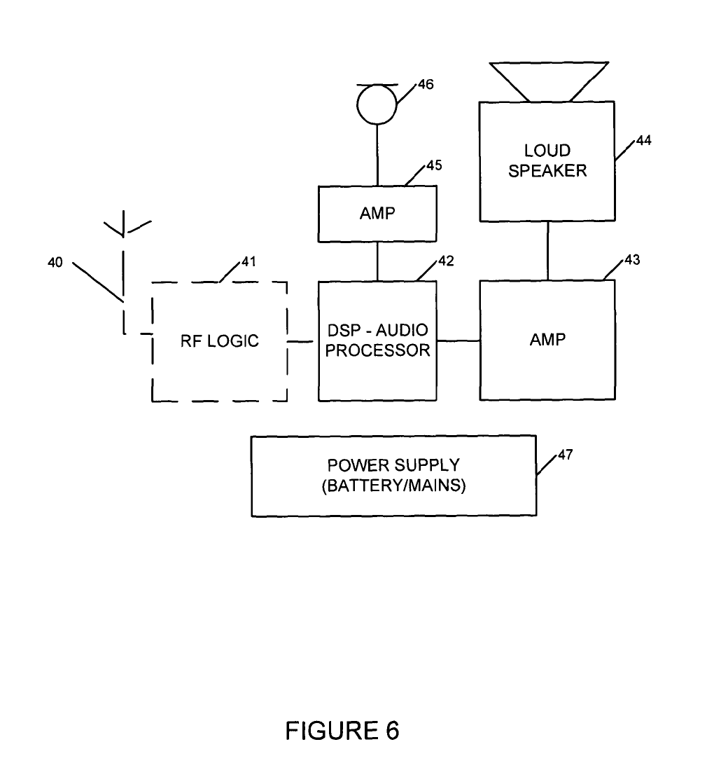

FIG. 6 illustrates the structure of the audio components of a handset in accordance with one embodiment of the present invention.

The handset is provided with a wireless antenna 40 for the transmission and reception of radio frequency (RF) modulated audio signals. A Radio Frequency (RF) logic unit 41 is provided to down convert the received RF signals and to up convert the audio signals for transmission by the antenna 40.

A digital signal processor (DSP) 42 provides for audio signal processing. An amplifier (AMP) 43 is provided for amplifying the received audio signals to drive a loudspeaker 44 having a poor low frequency response i.e. having a poor or no response below 250-350 Hz, e.g. 100-300 Hz.

A microphone 46 is provided to receive audio inputs from the user. The audio input is amplified by an amplifier (AMP) 45 before being processed by the DSP 42. Although AMP 45 is shown separate to AMP 43, the same amplifier can be used for both functions.

The circuitry of the audio circuitry of the handset is powered by a power supply 45 which is battery power supply to enable the handset to be mobile, and it can be a supplemented with and recharged by a mains supply.

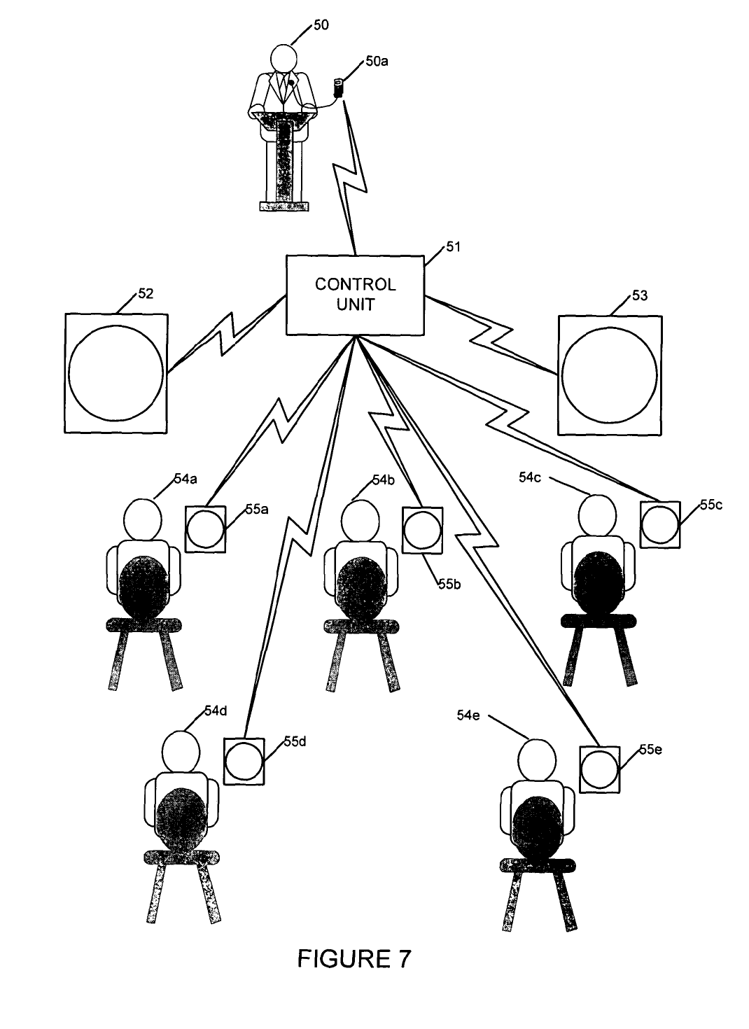

FIG. 7 illustrates an alternative embodiment of the present invention in which listeners are provided with personal low quality (mid to high frequency) loudspeakers for direct audio output to each respective user supported by a supplementary low frequency audio source.

Each listener 54a-e is provided with a portable communication unit 55a-e having a microphone and a mid to high frequency loudspeaker arranged adjacent to them. The units 55a-e are in wireless communication with a control unit 51 and the loudspeakers have a poor or no low frequency response i.e. below 250-350 Hz e.g. 100-300 Hz. Two low frequency loudspeaker units 52 and 53 are provided in the vicinity of the listeners 54a-e to provide low frequency audio output to all of the listeners to supplement the audio output of each mid to high frequency loudspeaker unit 55a-e. The low frequency loudspeaker units 52 and 53 are in wireless communication with the control unit 51 and have a good low frequency response i.e. below 250-350 Hz e.g. 100-300 Hz. Thus the control unit 51 broadcasts the audio signals to the low frequency loudspeaker units 52 and 53 and the units 55a-e. If the signal is the same, e.g. the same frequency range in the same channel, the low frequency loudspeaker units 52 and 53 can be provided with low pass filters to block the mid to high frequency component so that the loudspeakers in the units are only driven by the low frequency components i.e. below 250-350 Hz e.g. 100-300 Hz. Alternatively the low frequency loudspeaker units 52 and 53 can be provided with a separate low frequency signal e.g. on a separate channel. In which case, the control unit 51 has low pass filter circuitry to perform low pass filtering of the audio signal and has multichannel transmission circuitry to enable the low frequency signal to be transmitted on a second channel.

A speaker 50 is provided with a microphone unit 50a for the input of audio by the speaker 50 and the transmission of the audio signal over a wireless link to the control unit 51 for the broadcasting of the audio signal to the loudspeakers 52, 53 and the units 55a-e.

Thus in this embodiment of the present invention, a personal address system is provided which is simple and convenient to set up and benefits from enhance quality due to the low frequency supplemental source or sources of audio which are perceived psychoacoustically by listeners as omnidirectional.

In any of the embodiments described hereinabove, the provision of loudspeakers locally to listeners providing a direct sound source reduces the likelihood of time delays and echoes in an audio system and enhances intelligibility of the output sound. Also, the supplemental low frequency audio source or sources provides enhanced audio quality for listeners at a lower cost since high quality loudspeakers need not be placed locally to listeners. Further, the use of mobile communication handsets enables the simple configuration of the audio system and it facilitates the maintenance of the audio quality for listeners who wish to move during and audio session. The use of microphones provided in mobile communications handsets as the audio course for the audio system utilises an already provided audio input arrangement enabling listeners to become contributors in the audio session. The use of the direct local sound sources further reduces the likelihood of feedback.

In the described embodiments, the low frequency loudspeakers may be capable of outputting mid to high frequency sound. The filtering out of the mid to high frequency in the audio signal driving the loudspeakers avoids the output of mid to high frequency sound which can introduce detectible directionality of the sound and the perceived detection of time delays. Time delays between multiple low frequency sounds are perceived far less by the listeners.

Although the present invention has been described with reference to specific embodiments, modifications lie within the spirit and scope of the present invention as defined by the appended claims.

1. An audio communication system for generating an audio output for users in a region, the system comprising:
a plurality of portable communications devices, each said portable communication device being for use by a respective user in said region, each communications device comprising:
a microphone for inputting an audio signal by said user,
a loudspeaker for generating an audio output for said user, said loudspeaker being adapted to output said audio output in at least a first frequency band, and
a wireless interface for wireless communication to transmit said audio signal from said microphone and receive audio signal derived from a said microphone of at least one other said communications device in said region for generating said audio output by said loudspeaker;
at least one low frequency loudspeaker device having an interface for receiving audio signal derived from said microphone of at least one said communications device in said region, and a low frequency loudspeaker adapted to output a low frequency audio output in said region only in a second frequency band lower than said first frequency band; and
a control unit for communicating with and controlling communications of said wireless interfaces and the or each said interface, wherein said control unit is adapted to receive said audio signal derived from said microphone of at least one said communications device in said region and to broadcast said audio signal to said wireless interfaces and said at least one low frequency loudspeaker device.

2. The audio communication system of claim 1, wherein said interface of said at least one low frequency loudspeaker device is adapted to receive said audio signal for said first and second frequency band, and said at least one low frequency loudspeaker device includes a low pass filter to pass only said second frequency band to drive said low frequency loudspeaker.

3. The audio communication system of claim 1, wherein said interface of said at least one low frequency loudspeaker device is adapted to receive said audio signal for only said second frequency band to drive said low frequency loudspeaker.

4. The audio communication system of claim 1, wherein a said portable communications device is adapted to operate as said control unit to communicate with and control communications of said wireless interfaces and said interface.

5. The audio communication system of claim 1, wherein said interface of at least one of said at least one low frequency loudspeaker device comprises a wireless interface for wireless communication to receive said audio signal.

6. The audio communication system of claim 1, wherein said wireless interface of each said portable communications device is adapted to transmit said audio signal in a first communications channel and to receive said audio signal in a second communications channel, said second communication channel being common to all said portable communications devices.

7. The audio communication system of claim 1, wherein said control unit is adapted to receive said audio signal derived from a plurality of audio sources, and to mix said audio signal for broadcast of said mixed audio signal to said wireless interfaces and said at least one low frequency loudspeaker device.

8. The audio communication system of claim 1, wherein at least one said loudspeaker of said portable communications devices is adapted to output a majority of said audio output in said first frequency band.

9. The audio communication system of claim 1, wherein at least one said loudspeaker of said portable communications devices is adapted to output only said audio output in said first frequency band.

10. An audio communication method for generating an audio output for users in a region, the method comprising:
providing a plurality of users with a respective plurality of portable communications devices in said region, each communications device comprising a microphone, a loudspeaker, and a wireless interface;
receiving an audio signal from a user using a said microphone of a said communications device;
transmitting said audio signal from said microphone and receiving an audio signal derived from a said microphone of at least one other said communications device in said region using said wireless interface;
generating an audio output in at least a first frequency band by said loudspeaker of said communications device for said user;
receiving an audio signal derived from said microphone of at least one other said communications device at an interface of at least one low frequency loudspeaker device; and
outputting a low frequency audio output in said region only in a second frequency band lower than said first frequency band using a low frequency loudspeaker.

11. The audio communication method of claim 10, wherein said interface of said at least one low frequency loudspeaker device receives said audio signal for said first and second frequency band, and said at least one low frequency loudspeaker device uses a low pass filter to pass only said second frequency band to drive said low frequency loudspeaker.

12. The audio communication method of claim 10, wherein said interface of said at least one low frequency loudspeaker device receives said audio signal for only said second frequency band to drive said low frequency loudspeaker.

13. The audio communication method of claim 10, including using a control unit to communicate with and control communications of said wireless interfaces and the or each said interface.

14. The audio communication method of claim 10, wherein a said portable communications device operates as a control unit to communicate with and control communications of said wireless interfaces and said interface.

15. The audio communication method of claim 10, wherein said interface of at least one of said at least one low frequency loudspeaker device uses wireless communication to receive said audio signals.

16. The audio communication method of claim 13, wherein said control unit receives said audio signal derived from said microphone of at least one other said communications device and broadcasts said audio signal to said wireless interfaces and said at least one low frequency loudspeaker device.

17. The audio communication method of claim 16, wherein said interface of at least one of said at least one low frequency loudspeaker device uses a wireless interface for wireless communication to receive said audio signal.

18. The audio communication method of claim 14, wherein said interface of at least one of said at least one low frequency loudspeaker device uses a wireless interface for wireless communication to receive said audio signal; and said portable communications device operates as a control unit to receive said audio signal derived from said microphone of at least one other said communications device and broadcasts said audio signal to said wireless interfaces and said at least one low frequency loudspeaker device.

19. The audio communication method of claim 10, wherein said wireless interface of each said portable communications device transmits said audio signal in a first communications channel and receives said audio signal in a second communications channel, said second communication channel being common to all said portable communications devices.

20. The audio communication method of claim 13, wherein said control unit receives said audio signal derived from a plurality of audio sources, and mixes said audio signal for broadcast of said mixed audio signal to said wireless interfaces and said at least one low frequency loudspeaker device.

21. The audio communication method of claim 14, wherein said portable communications device operating as a control unit receives said audio signals derived from a plurality of audio sources, and mixes said audio signals for broadcast of said mixed audio signals to said wireless interfaces and said at least one low frequency loudspeaker device.

22. The audio communication method of claim 10, wherein at least one said loudspeaker of said portable communications devices outputs a majority of said audio output in said first frequency band.

23. The audio communication method of claim 10, wherein at least one said loudspeaker of said portable communications devices outputs only said audio output in said first frequency band.
